(19) United States
(12) Patent Application Publication
(10) Pub. No.: US 2018/0019444 A1
(43) Pub. Date: Jan. 18, 2018

(54) LIGHT-EMITTING ELEMENT, DETECTION DEVICE, AND PROCESSING APPARATUS

(71) Applicant: Kabushiki Kaisha Toshiba, Minato-ku (JP)

(72) Inventors: Toshiya YONEHARA, Kawasaki (JP); Tomio ONO, Yokohama (JP); Tomoaki SAWABE, Taito (JP)

(73) Assignee: Kabushiki Kaisha Toshiba, Minato-ku (JP)

(21) Appl. No.: 15/706,030

(22) Filed: Sep. 15, 2017

Related U.S. Application Data
(63) Continuation of application No. PCT/JP2015/061695, filed on Apr. 16, 2015.

(51) Int. Cl. H01L 51/52; H05B 33/22; H01L 27/28; H05B 33/26

(52) U.S. Cl. CPC H01L 51/5268; H05B 33/26; H05B 33/22; H01L 27/288; H01L 51/5203; H01L 51/5275

(57) ABSTRACT

According to one embodiment, a light-emitting element includes a substrate, a first electrode, a first layer, a second electrode, a light-emitting layer, and a second layer. The substrate, the second electrode, and the first layer are light-transmissive. A refractive index of the first layer is lower than a refractive index of the substrate. At least a portion of the first layer is provided between the first electrode and a portion of the substrate. The second electrode is provided between the first electrode and at least a portion of the first layer. The light-emitting layer is provided between the first electrode and the second electrode. The second layer is light-transmissive. The second layer is configured to modify a travel direction of light incident on the second layer. At least a portion of the second layer is provided between the first electrode and at least a portion of the first layer.

### CROSS-REFERENCE TO RELATED APPLICATIONS

This is a continuation application of International Application PCT/JP2015/061695, filed on Apr. 16, 2015; the entire contents of which are incorporated herein by reference.

### FIELD

Embodiments described herein relate generally to a light-emitting element, a detection device, and a processing apparatus.

### BACKGROUND

There is technology that detects a biological signal by irradiating light radiated from a light-emitting element onto a living body. In particular, it is desirable to develop a light-emitting element more suited to the detection of a pulse wave having a faint output signal.

### BRIEF DESCRIPTION OF THE DRAWINGS

FIG. 1A and FIG. 1B are schematic views illustrating an example of a light-emitting element according to a first embodiment;

FIG. 2 is a schematic view illustrating another example of the light-emitting element according to the first embodiment;

FIG. 3A to FIG. 3C and FIG. 4A to FIG. 4D are schematic cross-sectional views illustrating a part of the light-emitting element according to the first embodiment;

FIG. 5A and FIG. 5B are schematic views illustrating other examples of the light-emitting element according to the first embodiment;

FIG. 6A to FIG. 6C are schematic bottom views and schematic cross-sectional views illustrating light-emitting elements used in a simulation;

FIG. 7A and FIG. 7B are schematic views illustrating examples of optical paths of the light-emitting elements;

FIG. 8A to FIG. 8D, FIG. 9A to FIG. 9D, FIG. 10, FIG. 11, FIG. 12A, and FIG. 12B are graphs illustrating characteristics of the light-emitting element according to the first embodiment;

FIG. 13A and FIG. 13B are schematic cross-sectional views illustrating an example of a detection device according to the first embodiment;

FIG. 14A and FIG. 14B are schematic views illustrating an example of a light-emitting element according to a second embodiment;

FIG. 15 is a schematic cross-sectional view illustrating an example of a detection device using the light-emitting element according to the second embodiment;

FIG. 16 and FIG. 17 are schematic views illustrating an example of a processing apparatus including the light-emitting element according to the embodiment;

FIG. 18A, FIG. 18B, FIG. 19A to FIG. 19C, FIG. 20A to FIG. 20C, FIG. 21A, and FIG. 21B are schematic views illustrating a pulse wave being measured using the light-emitting element 100 according to the first embodiment;

FIG. 22A to FIG. 22C are schematic views illustrating processing apparatuses including the light-emitting element according to the embodiment;

FIG. 23A to FIG. 23E are schematic views illustrating applications of processing apparatuses including the light-emitting element according to the embodiment; and

FIG. 24 is a schematic view illustrating a system using the processing apparatuses illustrated in FIGS. 23A to 23E.

### DETAILED DESCRIPTION

According to one embodiment, a light-emitting element includes a substrate, a first electrode, a first layer, a second electrode, a light-emitting layer, and a second layer. The substrate is light-transmissive. The first layer has a refractive index lower than a refractive index of the substrate. The first layer is light-transmissive. At least a portion of the first layer is provided between the first electrode and a portion of the substrate. The second electrode is provided between the first electrode and at least a portion of the first layer. The second electrode is light-transmissive. The light-emitting layer is provided between the first electrode and the second electrode. The second layer is light-transmissive. The second layer is configured to modify a travel direction of light incident on the second layer. At least a portion of the second layer is provided between the first electrode and at least a portion of the first layer.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described thereinabove are marked with like reference numerals, and a detailed description is omitted as appropriate.

### First Embodiment

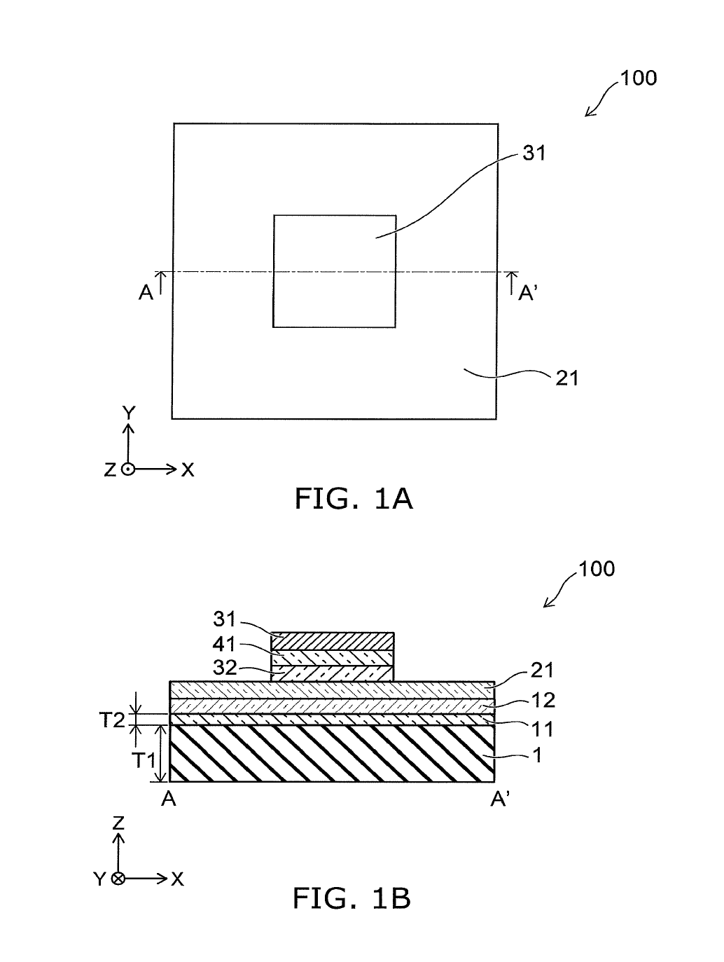

FIG. 1A and FIG. 1B are schematic views illustrating an example of a light-emitting element according to a first embodiment. FIG. 1A is a schematic plan view; and FIG. 1B is an A-A′ schematic cross-sectional view of FIG. 1A. As illustrated in FIGS. 1A and 1B, the light-emitting element 100 includes a substrate 1, a first layer 11, a second layer 12, a light-transmitting layer 21, a second electrode 32, a light-emitting layer 41, and a first electrode 31. For example, the light-emitting element 100 is used to detect a biological signal such as a pulse wave, etc.

A direction from the second electrode 32 toward the first electrode 31 is taken as a first direction. For example, the first direction corresponds to a Z-direction illustrated in FIGS. 1A and 1B.

At least a portion of the first layer 11 is provided between at least a portion of the substrate 1 and a portion of the first electrode 31 in the first direction. The second electrode 32 is provided between the first electrode 31 and at least a portion of the first layer 11 in the first direction.

At least a portion of the second layer 12 is provided between the first electrode 31 and at least a portion of the first layer 11 in the first direction. As an example, a portion of the second layer 12 is provided between the second electrode 32 and a portion of the first layer 11 in the first direction as illustrated in FIGS. 1A and 1B. The light-emitting layer 41 is provided between the first electrode 31 and the second electrode 32 in the first direction.

The refractive index of the first layer 11 is lower than the refractive index of the substrate 1. The refractive index of the second layer 12 is higher than the refractive index of the first layer 11. The refractive index of the second layer 12 is, for example, the same as or higher than the refractive index of the substrate 1. More favorably, the refractive index of the second layer 12 is the same as or higher than the refractive index of the second electrode 32 or the refractive index of the light-emitting layer 41. Compared to the case where the refractive index of the second layer 12 is lower than the refractive index of the light-emitting layer 41, the proportion of the light radiated from the light-emitting layer 41 that reaches the second layer 12 can be increased if the refractive index of the second layer 12 is the same as or higher than the refractive index of the light-emitting layer 41. This is because if the refractive index of the second layer 12 is lower than that of the light-emitting layer 41, the critical angle that is determined by the refractive index of the second layer 12 and the refractive index of the light-emitting layer 41 exists between the second layer 12 and the light-emitting layer 41. The second layer 12 is configured to modify the travel direction of the light incident on the second layer 12 inside the layer of the second layer 12. By providing the light-transmitting layer 21, for example, the unevenness of the surface of the second layer 12 is planarized. Thereby, the likelihood of an electrical disconnection of the second electrode 32, etc., occurring is reduced. It is sufficient for the light-transmitting layer 21 to be provided as necessary; and the light-transmitting layer 21 is not essential in the light-emitting element 100.

Light is radiated from the light-emitting layer 41 by carriers being injected into the light-emitting layer 41 from the first electrode 31 and the second electrode 32. The light-emitting layer 41 includes, for example, an organic substance. The noise is smaller for the light radiated from a light-emitting element using a light-emitting layer including an organic substance than for the light radiated from a light-emitting element using a light-emitting layer including an inorganic compound. Therefore, the light that is radiated from the light-emitting element using the light-emitting layer including the organic substance is suited to applications that detect a detection object such as a pulse wave, etc., in which the signal that is output is faint.

The substrate 1, the first layer 11, the second layer 12, the light-transmitting layer 21, and the second electrode 32 may transmit the light radiated from the light-emitting layer 41. In other words, the substrate 1, the first layer 11, the second layer 12, the light-transmitting layer 21, and the second electrode 32 are light-transmissive. The first electrode 31 may be light-reflective and may reflect the light radiated from the light-emitting layer 41.

The light that is radiated from the light-emitting layer 41 is, for example, visible light. In other words, the light that is radiated from the light-emitting layer 41 may be one of red, orange, yellow, green, or blue light or a combination of such light. The light that is radiated from the light-emitting layer 41 may be ultraviolet light or infrared light.

In the light-emitting element 100 according to the embodiment as described above, at least a portion of the first layer 11 is provided between the first electrode 31 and a portion of the substrate 1; and at least a portion of the second layer 12 is provided between the first electrode 31 and at least a portion of the first layer 11. By employing such a configuration, it is possible to increase the amount of the light radiated into the space overlapping the light-emitting layer 41 in the first direction. In other words, according to the embodiment, a light-emitting element is provided that is suited to an application detecting a biological signal such as a pulse wave, etc., in which it is desirable to irradiate light into a designated region.

Examples of the components will now be described.

The substrate 1 includes, for example, glass. The refractive index of the substrate 1 is, for example, not less than 1.4 and not more than 2.2. A thickness T1 along the first direction of the substrate 1 is, for example, 0.05 to 2.0 mm.

The refractive index of the first layer 11 may be, for example, 1.4 or less. In the case where the refractive index of the first layer 11 is 1.4 or less, the first layer 11 includes, for example, a polymer. More desirably, the refractive index of the first layer 11 is 1.1 or less. In the case where the refractive index of the first layer 11 is 1.1 or less, the first layer 11 includes, for example, a silica aerogel.

A thickness T2 of the first layer 11 may be 0.01 to 100 μm. Another layer may be provided between the substrate 1 and the first layer 11. For example, a light-transmitting layer that includes SiO₂ may be provided between the substrate 1 and the first layer 11. For example, the light-transmitting layer that includes SiO₂ is provided to reduce the unevenness of the surface of the substrate 1.

When viewed from the first direction, the configuration of the first electrode 31, the configuration of the light-emitting layer 41, and the configuration of the second electrode 32 are, for example, squares as illustrated in FIG. 1A. Other than rectangles and quadrilaterals, these configurations may be polygons, circles, or ellipses. These configurations are arbitrary.

The material of the first electrode 31 may include, for example, at least one of aluminum, silver, or gold. The first electrode 31 includes, for example, an alloy of magnesium and silver.

The material of the second electrode 32 may include, for example, ITO (Indium Tin Oxide). The material of the second electrode 32 may include, for example, a conductive polymer such as PEDOT:PSS, etc. The material of the second electrode 32 may include, for example, a metal such as aluminum, silver, etc. In the case where the material of the second electrode 32 includes a metal, it is favorable for the thickness of the second electrode 32 to be 5 to 20 nm.

The light-emitting layer 41 includes, for example, a material of at least one of Alq₃ (tris(8-hydroxyquinolinolato)aluminum), F8BT (poly(9,9-dioctylfluorene-co-benzothiadiazole)), or PPV (polyparaphenylene vinylene).

Or, the light-emitting layer 41 may include a mixed material containing a host material and a dopant added to the host material. The host material includes, for example, at least one of CBP (4,4′-N,N′-bis dicarbazolyl-biphenyl), BCP (2,9-dimethyl-4,7 diphenyl-1,10-phenanthroline), TPD (2,9-dimethyl-4,7 diphenyl-1,10-phenanthroline), PVK (polyvinyl carbazole), or PPT (poly(3-phenylthiophene)). The dopant material includes, for example, at least one of Flrpic (iridium(III)-bis(4,6-di-fluorophenyl)-pyridinate-N,C2′-picolinate), Ir(ppy)₃ (tris(2-phenylpyridine)iridium), or Flr6 (bis(2,4-difluorophenylpyridinato)-tetrakis(1-pyrazolyl)borate-iridium(III)).

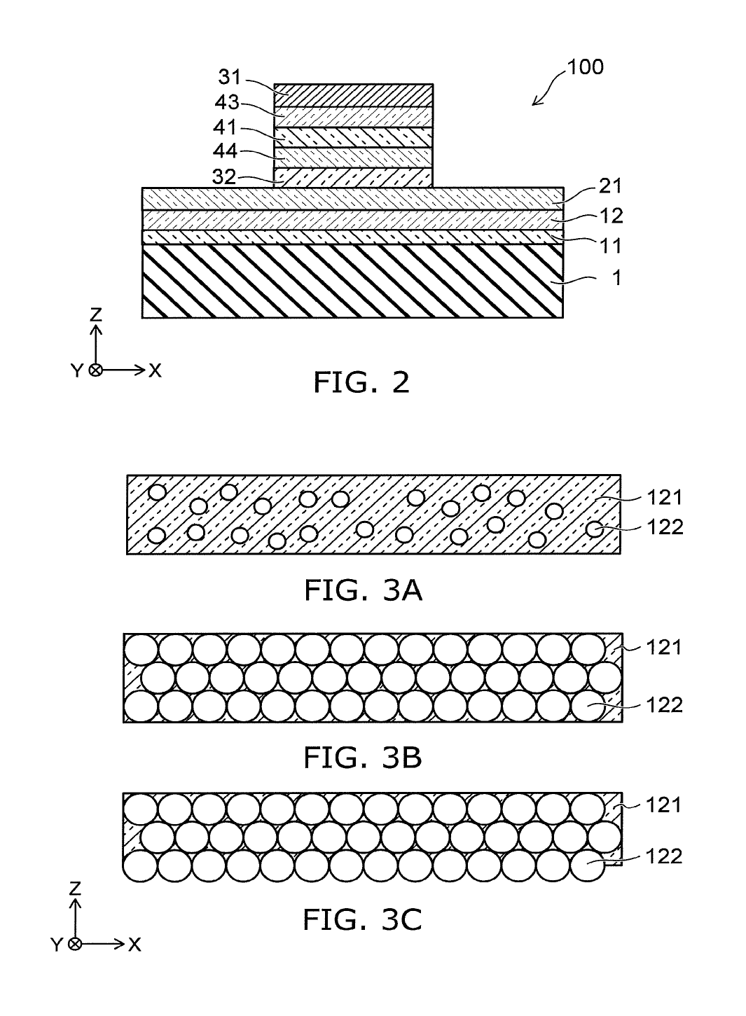

FIG. 2 is a schematic view illustrating another example of the light-emitting element according to the first embodiment. As illustrated in FIG. 2, a third layer 43 may be provided between the first electrode 31 and the light-emitting layer 41; and a fourth layer 44 may be provided between the second electrode 32 and the light-emitting layer 41.

The third layer 43 functions as, for example, an electron injection layer. The third layer 43 may function as an electron transport layer. Or, the third layer 43 may include a layer that functions as an electron injection layer and a layer that functions as an electron transport layer.

The material of the third layer 43 may include, for example, Alq₃, BAlq, POPy₂, Bphen, 3TPYMB, etc. In the case where these materials are used, the third layer 43 functions as an electron transport layer.

Or, the material of the third layer 43 may include, for example, LiF, CsF, Ba, Ca, etc. In the case where these materials are used, the third layer 43 functions as an electron injection layer.

The fourth layer 44 functions as, for example, a hole injection layer. The fourth layer 44 may function as a hole transport layer. Or, the fourth layer 44 may include a layer that functions as a hole injection layer and a layer that functions as a hole transport layer.

The material of the fourth layer 44 may include, for example, α-NPD, TAPC, m-MTDATA, TPD, TCTA, etc. In the case where these materials are used, the fourth layer 44 functions as a hole transport layer.

Or, the material of the fourth layer 44 may include, for example, PEDPOT:PSS, CuPc, MoO₃, etc. In the case where these materials are used, the fourth layer 44 functions as a hole injection layer.

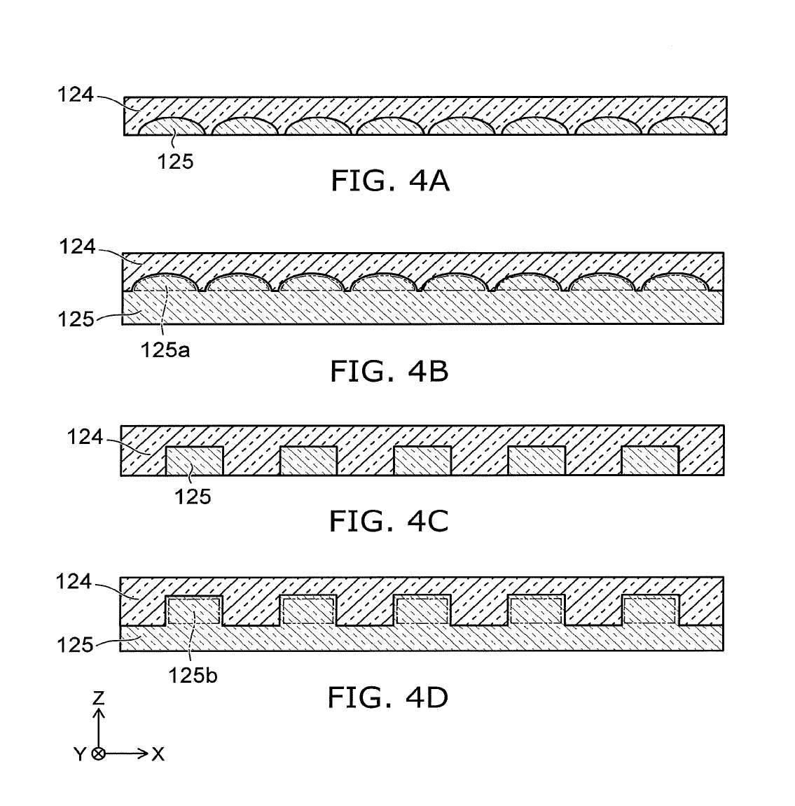

FIG. 3A to FIG. 3C and FIG. 4A to FIG. 4D are schematic cross-sectional views illustrating the second layer 12. In the configuration of the second layer 12 illustrated in the examples of FIG. 3A to FIG. 3C, the light that is incident on the second layer 12 may be scattered in the interior of the second layer 12. In the configuration of the second layer 12 illustrated in the examples of FIG. 4A to FIG. 4D, the light that is incident on the second layer 12 may be refracted in the interior of the second layer 12.

As illustrated in FIG. 3A to FIG. 3C, the second layer 12 includes, for example, a support portion 121 and multiple particles 122. For example, the support portion 121 spreads along a first plane perpendicular to the first direction. The first plane is, for example, a plane including an X-direction and a Y-direction illustrated in FIGS. 1A and 1B.

In the example illustrated in FIG. 3A, the multiple particles 122 are provided to be separated from each other; and the support portion 121 is provided around each of the particles. In the example illustrated in FIG. 3B, at least a portion of the multiple particles 122 is provided to be in contact with each other; and the support portion 121 is provided around each of the particles.

In the example illustrated in FIG. 3C, a portion of the multiple particles 122 is exposed outside the support portion 121. The support portion 121 is provided around at least a portion of each of the particles. More specifically, a portion of the support portion 121 is provided around a portion of the particles 122 exposed outside the support portion 121. Another portion of the support portion 121 is provided around another portion of the multiple particles 122.

The support portion 121 includes, for example, at least one of a polymer or a resin. Polysiloxane, polyimide, polymethyl methacrylate, etc., may be used as the polymer. The particles 122 include, for example, fine particles of at least one of silica, polystyrene, zirconium oxide, or titanium oxide. Voids may be provided instead of the particles 122.

It is desirable for the absolute value of the difference between the refractive index of the support portion 121 and the refractive index of at least one of the particles 122 to be 0.1 or more. More desirably, the absolute value of the difference of these refractive indexes is 0.2 or more. By setting the absolute value of the difference of these refractive indexes to be 0.1 or more, a sufficient scattering property for the light incident on the second layer 12 is obtained. The scattering probability due to the particles 122 increases as the difference of the refractive indexes increases. A high scattering ability is obtained more easily at a lower density as the difference of the refractive indexes increases.

Or, as illustrated in FIG. 4A to FIG. 4D, the second layer 12 includes, for example, a first portion 124 and a second portion 125. The second portion 125 is provided between the first portion 124 and the substrate 1. The refractive index of the second portion 125 is lower than the refractive index of the first portion 124.

In the example illustrated in FIG. 4A, the second portion 125 is multiply provided in the second direction. The second portions 125 also may be multiply provided in a third direction. Or, the second portions 125 may extend in the third direction. The second direction is a direction perpendicular to the first direction and is, for example, the X-direction illustrated in FIGS. 4A to 4D. The third direction is a direction perpendicular to the first direction and crossing the second direction and is, for example, the Y-direction illustrated in FIGS. 4A to 4D.

The first portion 124 spreads along the first plane. Each of the second portions 125 is surrounded with the first portion 124 along the first plane. The second portions 125 have hemispherical configurations. Therefore, the thickness along the first direction of the first portion 124 changes periodically and continuously in the second direction.

Or, as illustrated in FIG. 4B, the second portion 125 may spread along the first plane. The second portion 125 includes a hemispherical portion 125a that is surrounded with the first portion 124 along the first plane. For example, the hemispherical portion 125a is multiply provided in the second direction and the third direction.

As illustrated in FIG. 4C, the second portion 125 may have a surface along the first direction and a surface along the second direction. The thickness along the first direction of the first portion 124 changes periodically in a staircase configuration. Or, the second portion 125 may spread along the first plane as illustrated in FIG. 4D. The second portion 125 includes a protruding portion 125b having a surface along the first direction and a surface along the second direction. For example, the protruding portion 125b is multiply provided in the second direction; and each of the protruding portions 125b extends in the third direction.

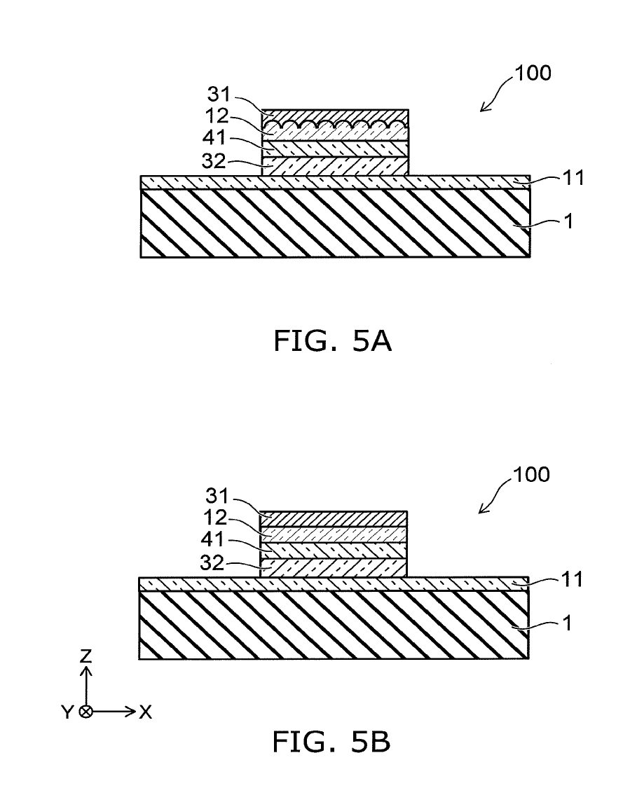

As illustrated in FIG. 5A and FIG. 5B, the second layer 12 may be provided somewhere other than between the first layer 11 and the second electrode 32. FIG. 5A and FIG. 5B are schematic views illustrating other examples of the light-emitting element according to the first embodiment. The second layer 12 is provided between the first electrode 31 and the light-emitting layer 41. The second layer 12 may be provided both between the first layer 11 and the second electrode 32 and between the first electrode 31 and the light-emitting layer 41. In other words, the second layer 12 is provided in at least one of a first position between the first layer 11 and the second electrode 32 or a second position between the first electrode 31 and the light-emitting layer 41.

In the example illustrated in FIG. 5A, the interface between the second layer 12 and the first electrode 31 has an uneven structure. As one specific example, the distance between the second electrode 32 and the interface between the second layer 12 and the first electrode 31 changes periodically in the second direction. In this example, the second layer 12 may function as an electron injection layer or an electron transport layer. Or, the second layer 12 may include a layer that functions as an electron injection layer and a layer that functions as an electron transport layer.

In the example illustrated in FIG. 5B, the second layer 12 has a structure illustrated in any of FIG. 3A to FIG. 3C. In such a case, the support portion 121 that is included in the second layer 12 includes a conductive material. The support portion 121 that is included in the second layer 12 functions as, for example, an electron transport layer. The support portion 121 that is included in the second layer 12 functions as, for example, an electron injection layer.

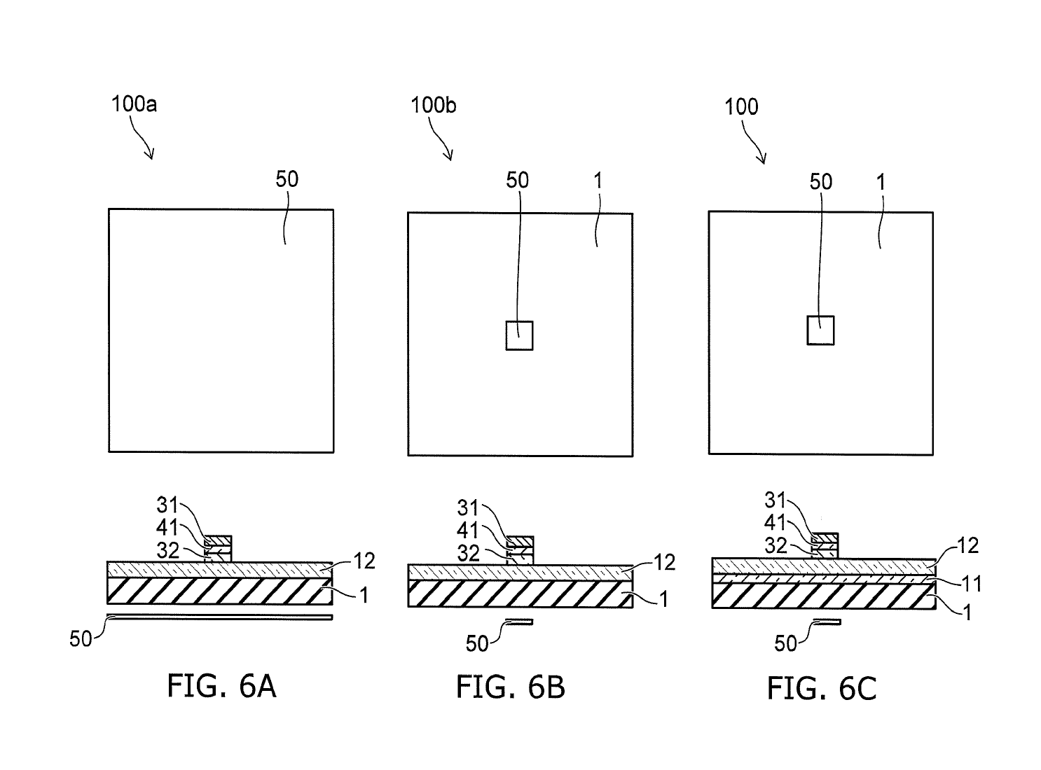

FIG. 6A to FIG. 6C are schematic bottom views and schematic cross-sectional views illustrating light-emitting elements used in a simulation. FIG. 6A illustrates a light-emitting element 100a according to a first reference example; and FIG. 6B illustrates a light-emitting element 100b according to a second reference example. FIG. 6C illustrates the light-emitting element 100 according to the first embodiment. In the simulation, the light-emitting elements 100a, 100b, and 100 are set as follows.

The substrate 1 is a square of which one side is 24 mm. The second layer 12 is a square of which one side is 24 mm. The first electrode 31, the second electrode 32, and the light-emitting layer 41 are squares of which one side is 2 mm. The material of the first electrode 31 is aluminum. The thickness of the first electrode 31 is 150 nm. The refractive index of the second electrode 32 is 1.8. The thickness of the second electrode 32 is 100 nm. The refractive index of the light-emitting layer 41 is 1.8. The thickness of the light-emitting layer 41 is 100 nm. In the second layer 12, the particles 122 having a particle size 1 μm and a refractive index of 2.5 are dispersed at a density 1.0×10¹² cm⁻³ in the support portion 121 having a refractive index of 1.8. A Mie scattering model is used as the light scattering model of the second layer 12.

In the first reference example, the surface area of a light detector 50 is the same as the surface area of the substrate 1. As a result of the simulation performed for the first reference example, the light extraction efficiency was calculated to be 38.7%. Here, the light extraction efficiency illustrates the proportion of the light radiated from the light-emitting layer 41 that is incident on the light detector 50.

In the second reference example, the surface area of the light detector 50 is the same as the surface area of the light-emitting layer 41. As a result of the simulation performed for the second reference example, the light extraction efficiency was calculated to be 21.0%. Even though the light-emitting element according to the second reference example has the same structure as the light-emitting element according to the first reference example, the light extraction efficiency of the second reference example is lower than the light extraction efficiency of the first reference example. From this result, in the first reference example and the second reference example, it can be seen that the light that is emitted to the outside from the substrate 1 includes much light emitted outside the region overlapping the light-emitting layer 41 in the first direction.

Compared to the light-emitting element 100b according to the second reference example, the light-emitting element 100 according to the first embodiment further includes the first layer 11. The refractive index of the first layer 11 is 1.1. One side of the first layer 11 was set to 24 mm. As a result of the simulation performed for the light-emitting element 100, the light extraction efficiency was calculated to be 29.9%. Comparing with the second reference example, it can be seen that the proportion of the light emitted to the outside from the substrate 1 that is emitted in the region overlapping the light-emitting layer 41 in the first direction is increased by providing the first layer 11.

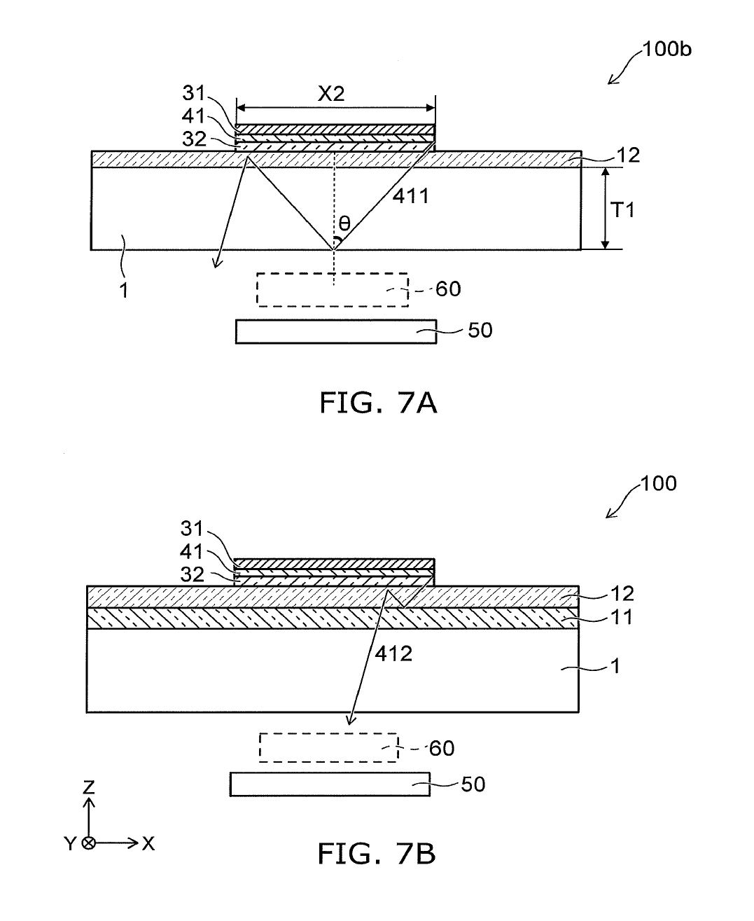

FIG. 7A and FIG. 7B are schematic views illustrating examples of optical paths of the light-emitting elements. Specifically, an example of the optical path of the light-emitting element 100b according to the second reference example is illustrated in FIG. 7A; and an example of the optical path of the light-emitting element 100 according to the embodiment is illustrated in FIG. 7B. In the examples illustrated in FIG. 7A and FIG. 7B, the length along the second direction of the light detector 50 is the same as the length along the second direction of the light-emitting layer 41. Light 411 and 412 illustrates the light radiated from the end portion in the second direction of the light-emitting region.

In the light-emitting element 100b, the light 411 passes through the second layer 12 and is incident on the substrate 1. When the light 411 is incident on the lower surface of the substrate 1 at an angle that is larger than the critical angle of the total internal reflection determined using the refractive index of the substrate 1, the light 411 is reflected at the lower surface.

The light 411 that is reflected at the lower surface is incident on the second layer 12 and is scattered in the interior of the second layer 12. A portion of the scattered light again travels toward the substrate 1. The angle of the travel direction of the light with respect to the lower surface of the substrate 1 is changed by the light being scattered by the second layer 12. If the angle of the travel direction of the light with respect to the lower surface of the substrate 1 is smaller than the critical angle, the light travels outside without being reflected at the lower surface of the substrate 1.

In the light-emitting element 100 according to the embodiment, the light 412 passes through the second layer 12 and travels toward the first layer 11. At this time, the light 412 is reflected at the upper surface of the first layer 11 if the light 412 is incident on the upper surface of the first layer 11 at an angle that is larger than the critical angle of the total internal reflection. The travel direction of the reflected light 412 is modified by the second layer 12. In other words, the light 412 is scattered inside the second layer 12. A portion of the scattered light travels toward the light detector 50 by passing through the substrate 1.

The refractive index of the first layer 11 is lower than the refractive index of the substrate 1. Accordingly, the light that is radiated from the light-emitting layer 41 and travels toward the light detector 50 at an angle that will be reflected at the lower surface of the substrate 1 is reflected toward the second layer 12 at the interface between the first layer 11 and the second layer 12. In other words, the light that cannot pass through to the outside from the substrate 1 is reflected at the interface between the first layer 11 and the second layer 12 before being incident on the substrate 1.

By providing the first layer 11, the optical path when the light is radiated from the light-emitting layer 41, reflected, and subsequently incident on the second layer 12 can be shortened. In particular, by shortening the distance of the optical path along directions perpendicular to the first direction, it is possible to reduce the amount of the light traveling toward the region outside the region overlapping the light-emitting region in the first direction.

In the example illustrated in FIG. 7A, when the light 411 that is reflected at the lower surface of the substrate 1 travels to the space of the second layer 12 not overlapping the light-emitting region in the first direction, the likelihood of the light scattered by the second layer 12 being incident on the light detector 50 decreases.

In other words, the likelihood of the light 411 traveling toward somewhere other than the light detector 50 is high in the case where a length X2 along the second direction of the light-emitting region, the thickness T1 along the first direction of the substrate 1, and a refractive index n of the substrate 1 satisfy the following Formula (1).

$$X 2 < 2 \times T 1 \times tan ( arc sin \frac{1}{n} ) \qquad ( 1 )$$

Accordingly, the embodiment is particularly effective in the case where the length X2 satisfies Formula (1).

It is favorable for the thickness T2 of the first layer 11 to be thinner than the thickness T1 of the substrate 1. This is because in the case where the thickness T2 is thicker than the thickness T1, even if the optical path of the light 411 is modified by the first layer 11, the distance that the light 411 moves inside the layer of the first layer 11 in directions perpendicular to the first direction increases; and the amount of the light traveling toward the region outside the region overlapping the light-emitting region in the first direction increases.

The thickness T2 of the first layer 11 is, for example, thicker than 10 nm. More favorably, the thickness T2 of the first layer 11 is thicker than the wavelength of the light. This is because the amount of the light of which the optical path is not sufficiently modified by the first layer 11 increases in the case where the thickness T2 is thinner than the wavelength of the light. The light of which the optical path is not modified becomes an evanescent wave inside the first layer 11 and passes through the first layer 11 toward the substrate 1.

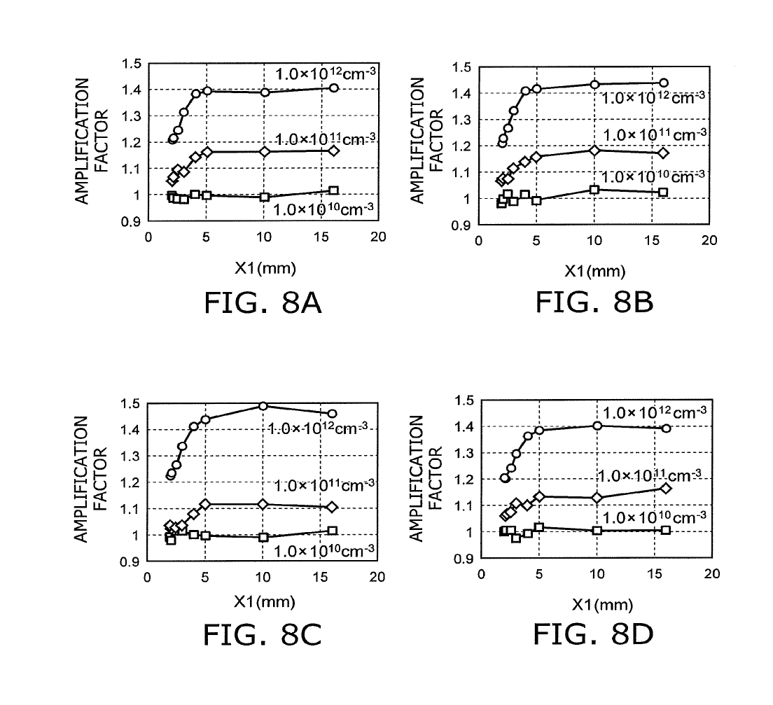

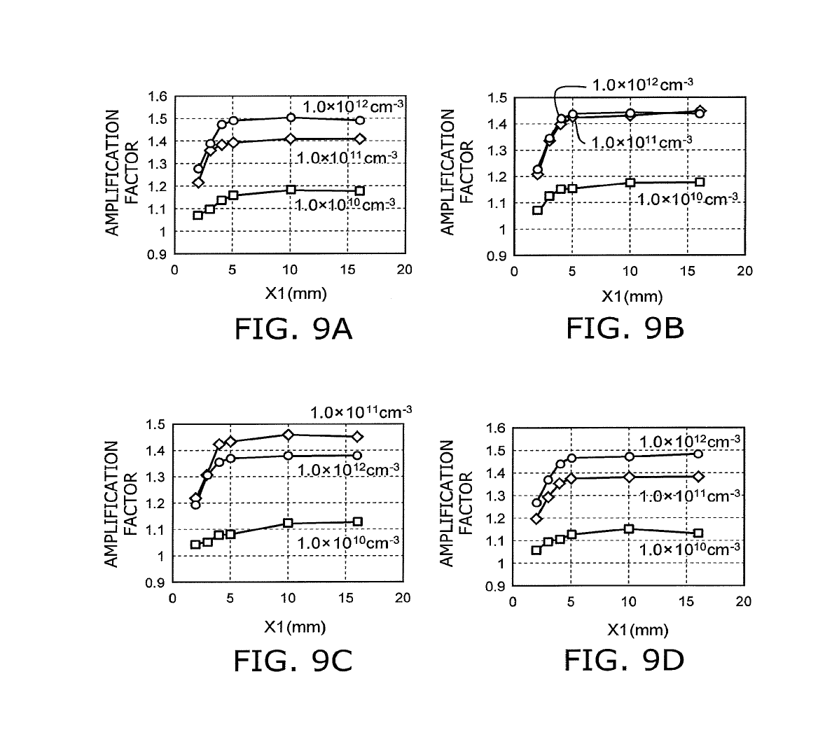

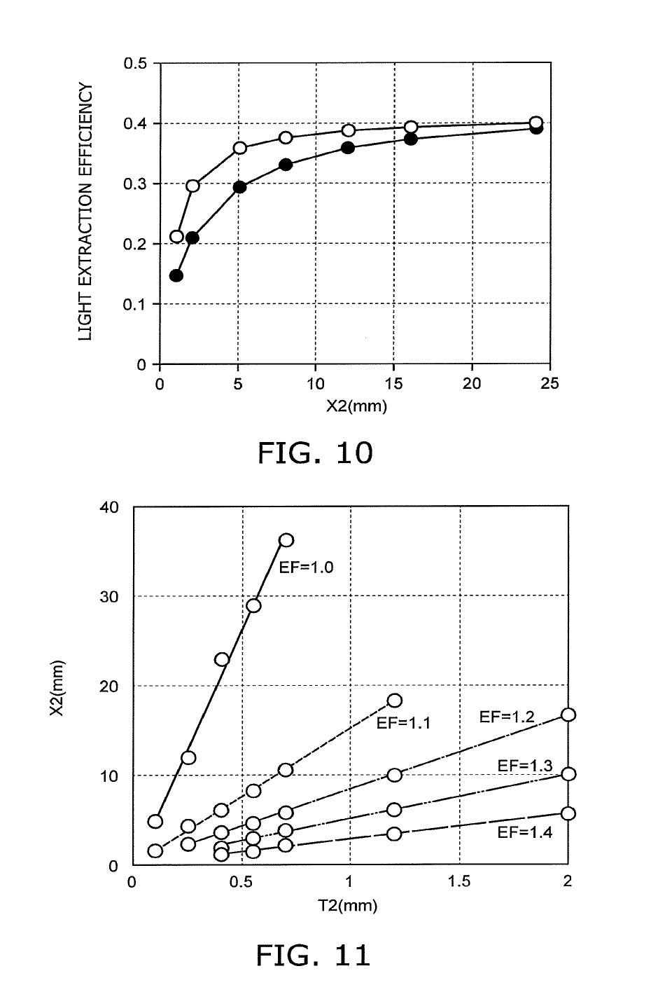

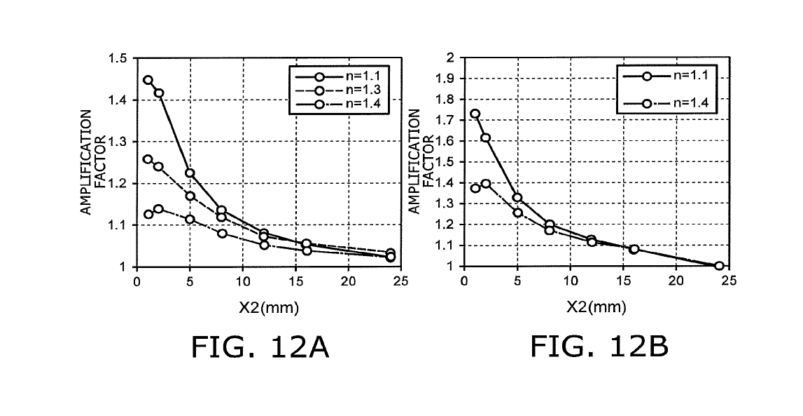

FIG. 8A to FIG. 8D and FIG. 9A to FIG. 9D are graphs illustrating a characteristic of the light-emitting element according to the first embodiment. Specifically, each graph of FIG. 8A to FIG. 9D is a simulation result illustrating the characteristic when the light emitted from the light-emitting element including the second layer 12 illustrated in FIG. 3A is detected by a light detector provided to be separated from the light-emitting element in the first direction.

In the simulation, the position of the light detector is set so that a portion of the substrate 1 is positioned between the light detector and the first electrode 31. A light-emitting region S of the light-emitting layer 41 positioned between the first electrode 31 and the second electrode 32 was set to be a square having one side of 2 mm. The light detector was set to have the same configuration and surface area as the light-emitting region S. The light detector detects the light amount of the light emitted from the substrate 1 in the region S that is incident on the light detector. In the simulation, the conditions are set as follows.

The refractive index of the support portion 121 is 1.8. The particle size of the particle 122 is 1 μm. The refractive index of the first layer 11 is 1.1. The refractive index of the substrate 1 is 1.5. The thickness of the substrate 1 is 0.7 mm. The first electrode 31 is aluminum. The thickness of the first electrode 31 is 150 nm. The refractive index of the second electrode 32 is 1.8. The thickness of the second electrode 32 is 100 nm. The refractive index of the light-emitting layer 41 is 1.8. The thickness of the light-emitting layer 41 is 100 nm.

In each of the graphs of FIG. 8A to FIG. 8D and FIG. 9A to FIG. 9D, the horizontal axis illustrates the length of the substrate 1 along the second direction. In the simulation, the length along the second direction of the first layer 11 and the length along the second direction of the second layer 12 are the same as the length in the second direction of the substrate 1. The vertical axis illustrates the amplification factor of the light amount detected by the light detector when a length X1 and the density of the particles 122 are changed.

The amplification factor is calculated by taking the light amount detected by the light detector for the light-emitting element of the light-emitting element 100 according to the first embodiment without the first layer 11 to be 1. The light amount that is detected by the light detector is calculated using ray tracing.

FIG. 8A to FIG. 8D illustrate the characteristic of the light-emitting element in the case where the thickness along the first direction of the second layer 12 is 1 μm. In the simulation illustrated in FIG. 8A, the refractive index of the particle 122 is set to 2.5. In FIG. 8B, the refractive index of the particle 122 is set to 2.2. In FIG. 8C, the refractive index of the particle 122 is set to 1.5. In FIG. 8D, the refractive index of the particle 122 is set to 1.0.

FIG. 9A to FIG. 9D illustrate the characteristic of the light-emitting element in the case where the thickness along the first direction of the second layer 12 is 10 μm. In the simulation illustrated in FIG. 9A, the refractive index of the particle 122 is set to 2.5. In FIG. 9B, the refractive index of the particle 122 is set to 2.2. In FIG. 9C, the refractive index of the particle 122 is set to 1.5. In FIG. 9D, the refractive index of the particle 122 is set to 1.0.

From FIG. 8A to FIG. 8D and FIG. 9A to FIG. 9D, it can be seen that the amplification factor increases as the density of the particles 122 increases. It can be seen that there is a tendency for the amplification factor to increase as the length X1 along the second direction increases. Comparing FIG. 8A to FIG. 8D and FIG. 9A to FIG. 9D, it can be seen that the amplification factor in the case where the thickness of the second layer 12 along the first direction is thick is higher than the amplification factor in the case where the thickness of the second layer 12 along the first direction is thin.

The characteristic of the light-emitting element 100 according to the first embodiment when the particle size of the particle 122 is 1 μm is described using FIG. 8A to FIG. 8D and FIG. 9A to FIG. 9D. It is recited in Res. Reports_Asahi_Glass_Co. Ltd., 62 (2012) that the characteristics of the light-scattering layer change due to the particle size of the scattering body and the density of the scattering bodies. Accordingly, not only in the case where the particle size of the scattering body is 1 μm but also in the case where the particle size of the scattering body is a different particle size, it is possible to obtain a characteristic similar to the characteristic of the light-emitting element 100 described in reference to FIG. 8A to FIG. 9D by appropriately changing the density of the scattering bodies.

For example, the particle size of the particle 122 may have a maximum of 100 μm. In the case where the second layer 12 is made by spin coating, the thickness of the support portion 121 has a maximum of about 10 μm due to the constraints of the viscosity of the material. Accordingly, in the case of such a support portion 121, it is favorable for the particle size of the particle 122 to have a maximum of 10 μm. It is desirable for the particle size of at least one particle 122 of the multiple particles 122 to be greater than 1/10 of the peak wavelength of the light. In the case where the particle size is greater than 1/10 of the peak wavelength of the light, the scattering follows a Mie scattering model.

In the case where the particle size of the particle 122 is sufficiently smaller than the wavelength of the light, the spatial resolution between the support portion 121 and the particles 122 disappears from the perspective of the light. In other words, in such a case, from the perspective of the light, the second layer 12 is a layer having the average refractive index of the refractive index of the support portion 121 and the refractive index of the particle 122; and the scattering ability of the second layer 12 for the light decreases.

FIG. 10, FIG. 11, FIG. 12A, and FIG. 12B are other graphs illustrating characteristics of the light-emitting element according to the first embodiment. Specifically, these graphs are simulation results illustrating characteristics when the light that is emitted outside the substrate 1 from the portion of the substrate 1 overlapping the light-emitting region S in the first direction is detected by a light detector having the same configuration and surface area as the light-emitting region S for the light-emitting element including the second layer 12 illustrated in FIG. 3A.

In FIG. 10, the horizontal axis illustrates the length along the second direction of the light-emitting region. The light-emitting region is the region of the light-emitting layer 41 positioned between the first electrode 31 and the second electrode 32 in the first direction. The vertical axis illustrates the proportion of the light incident on the light detector to the light radiated from the light-emitting region.

In FIG. 11, the horizontal axis illustrates the thickness of the substrate 1 along the first direction. The vertical axis illustrates the length of the light-emitting region along the second direction. In FIGS. 12A and 12B, the horizontal axis illustrates the length of the light-emitting region along the second direction. The vertical axis illustrates the amplification factor of the light extraction efficiency of the light-emitting element including the first layer 11 with respect to the light extraction efficiency of the light-emitting element not including the first layer 11.

In the light-emitting elements used in the simulation, the particle size of the particle 122 is set to 1 μm; the refractive index of the particle 122 is set to 2.5; the density of the particles 122 is set to 1.0×10¹² cm⁻³; the thickness along the first direction of the second layer 12 is set to 1.0 μm; and the length along the second direction of the substrate 1 is set to 200 mm.

In the simulation illustrated in FIG. 10 and FIG. 11, the refractive index of the first layer 11 is set to 1.1. In the simulation illustrated in FIG. 10, FIG. 12A, and FIG. 12B, the thickness along the first direction of the substrate 1 is set to 0.7 mm. In the simulation illustrated in FIG. 12A, the refractive index of the substrate 1 is set to 1.5. In the simulation illustrated in FIG. 12B, the refractive index of the substrate 1 is set to 1.8.

In the simulation illustrated in FIG. 10, FIG. 11, FIG. 12A, and FIG. 12B, the other conditions are as follows.

The first electrode 31 is aluminum. The thickness of the first electrode 31 is 150 nm. The refractive index of the second electrode 32 is 1.8. The thickness of the second electrode 32 is 100 nm. The refractive index of the light-emitting layer 41 is 1.8. The thickness of the light-emitting layer 41 is 100 nm.

In FIG. 10, the white dots illustrate the characteristic of the light-emitting element including the first layer 11 illustrated in FIGS. 1A and 1B; and the black dots illustrate the characteristic of the light-emitting element of the configuration illustrated in FIGS. 1A and 1B without the first layer 11. From FIG. 10, it can be seen that the efficiency increases as the length X2 lengthens. Additionally, it can be seen that the light-emitting element including the first layer 11 has a higher light extraction efficiency than the light-emitting element not including the first layer 11 regardless of the length X2.

In FIG. 11, EF illustrates the amplification factor of the light extraction efficiency of the light-emitting element including the first layer 11 with respect to the light extraction efficiency of the light-emitting element not including the first layer 11. As an example, the light extraction efficiency of the light-emitting element including the first layer 11 is 1.4 times the light extraction efficiency of the light-emitting element not including the first layer 11 for the combinations of the thickness T2 and the length X2 positioned on the straight line of EF=1.4.

From FIG. 11, it can be seen that the increase of the light extraction efficiency due to the first layer 11 becomes more pronounced as the length X2 decreases and the thickness T2 increases. The EF straight lines of FIG. 11 are represented by the following formulas.

EF=1.0: X2 (mm)=53.16×T2 (mm)−0.23

EF=1.1: X2 (mm)=15.03×T2 (mm)+0.24

EF=1.2: X2 (mm)=8.21×T2 (mm)+0.21

EF=1.3: X2 (mm)=4.95×T2 (mm)+0.19

EF=1.4: X2 (mm)=2.80×T2 (mm)+0.11

In other words, in the simulation results illustrated in FIG. 11, the increase of the extraction efficiency due to providing the first layer 11 is confirmed in the case where X2 (mm)<53.16×T2 (mm)−0.23 is satisfied. Further, from the simulation results illustrated in FIG. 11, it can be seen that it is more desirable when X2 (mm)<2.80×T2 (mm)+0.11.

From the simulation results illustrated in FIG. 12A and FIG. 12B, it can be seen that the increase of the extraction efficiency due to providing the first layer 11 becomes more pronounced as the refractive index of the first layer 11 decreases. Comparing FIG. 12A and FIG. 12B, it can be seen that the increase of the extraction efficiency due to providing the first layer 11 becomes more pronounced as the difference between the refractive index of the first layer 11 and the refractive index of the substrate 1 increases.

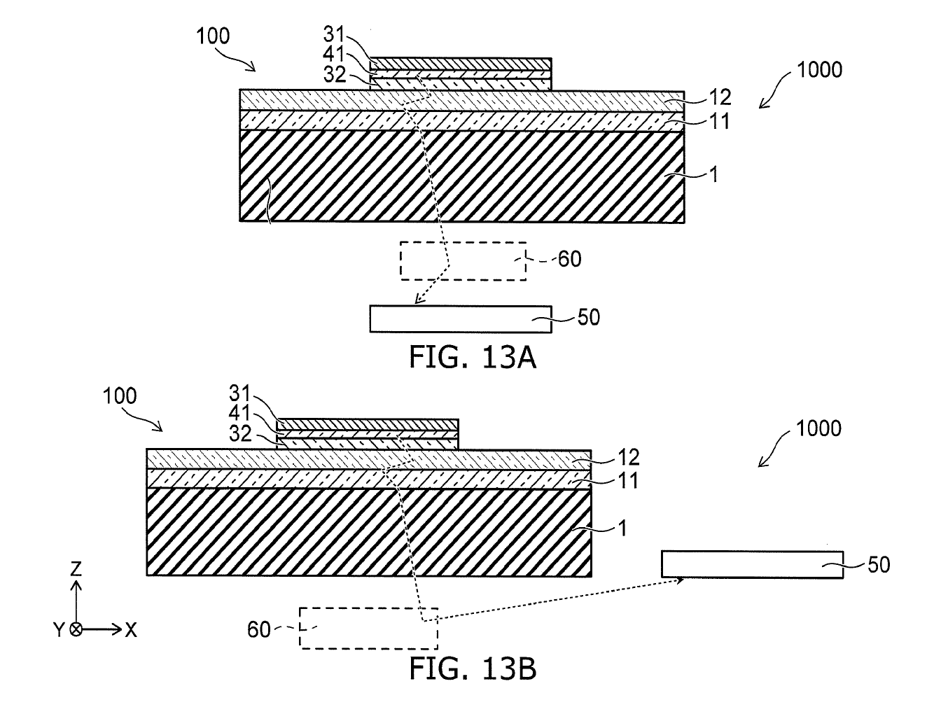

FIG. 13A and FIG. 13B are schematic cross-sectional views illustrating an example of a detection device according to the first embodiment. The detection device 1000 includes the light-emitting element 100, and the light detector 50 that detects the light radiated from the light-emitting layer 41. In FIGS. 13A and 13B, paths of the light radiated from the light-emitting layer 41 are illustrated by broken lines.

As illustrated in FIG. 13A, for example, at least a portion of the light detector 50 overlaps at least a portion of the first electrode 31, at least a portion of the second electrode 32, and at least a portion of the light-emitting layer 41 in the first direction. For example, a detection object 60 is disposed between the light detector 50 and the light-emitting element 100.

Or, as illustrated in FIG. 13B, at least a portion of the light detector 50 may be arranged with at least a portion of the light-emitting element 100 in the second direction or the third direction. In such a case, the light is radiated from the light-emitting element 100, is incident on the detection object 60, and is reflected by the detection object 60. The light detector 50 detects the light that is reflected by the detection object 60.

Because the light-emitting element 100 is included in the detection device 1000, the amount of the light irradiated on the detection object 60 and incident on the light detector 50 can be increased; and it is possible to increase the detection sensitivity and the detection precision of the detection device 1000.

### Second Embodiment

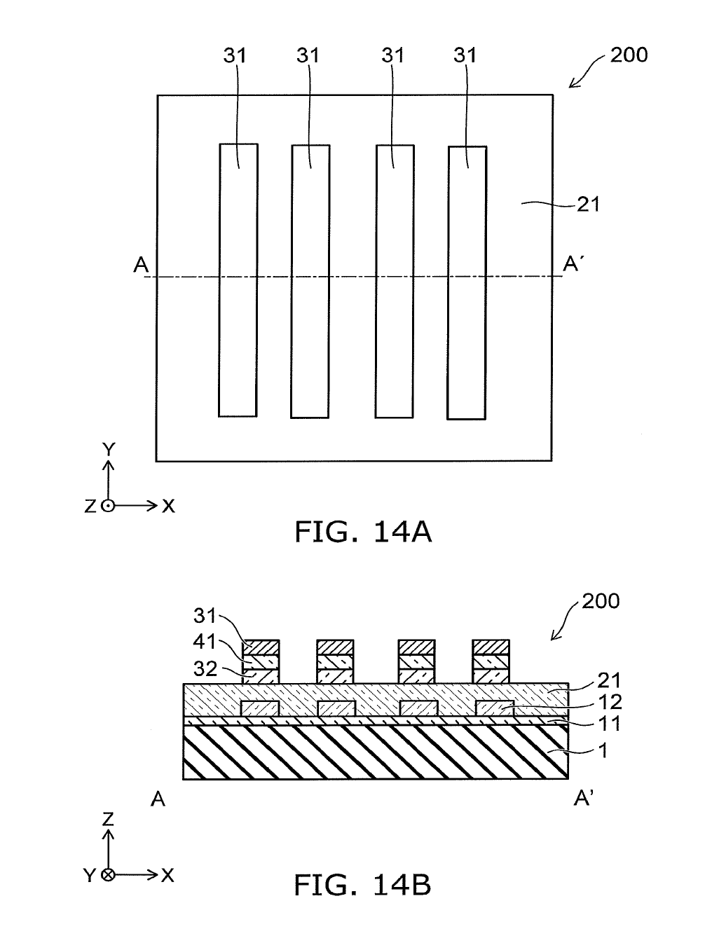

FIG. 14A and FIG. 14B are schematic views illustrating an example of a light-emitting element according to a second embodiment. FIG. 14A is a schematic plan view; and FIG. 14B is an A-A′ schematic cross-sectional view of FIG. 14A. The light-emitting element 200 includes the substrate 1, the first layer 11, the multiple second layers 12, the light-transmitting layer 21, the multiple second electrodes 32, the multiple light-emitting layers 41, and the multiple first electrodes 31.

As illustrated in FIG. 14A, the first electrode 31 is multiply provided in, for example, the second direction. The first electrodes 31 also may be multiply provided in the third direction. At least a portion of the first layer 11 is provided between a portion of the substrate 1 and each of the first electrodes 31. The second electrodes 32 are provided respectively between at least a portion of the first layer 11 and the first electrodes 31.

The light-emitting layers 41 are provided respectively between the first electrodes 31 and the second electrodes 32. The first layer 11 may be divided into a plurality in the second direction. In other words, the first layer 11 may be multiply provided in the second direction so that the first layers 11 are positioned respectively between a portion of the substrate 1 and the first electrodes 31.

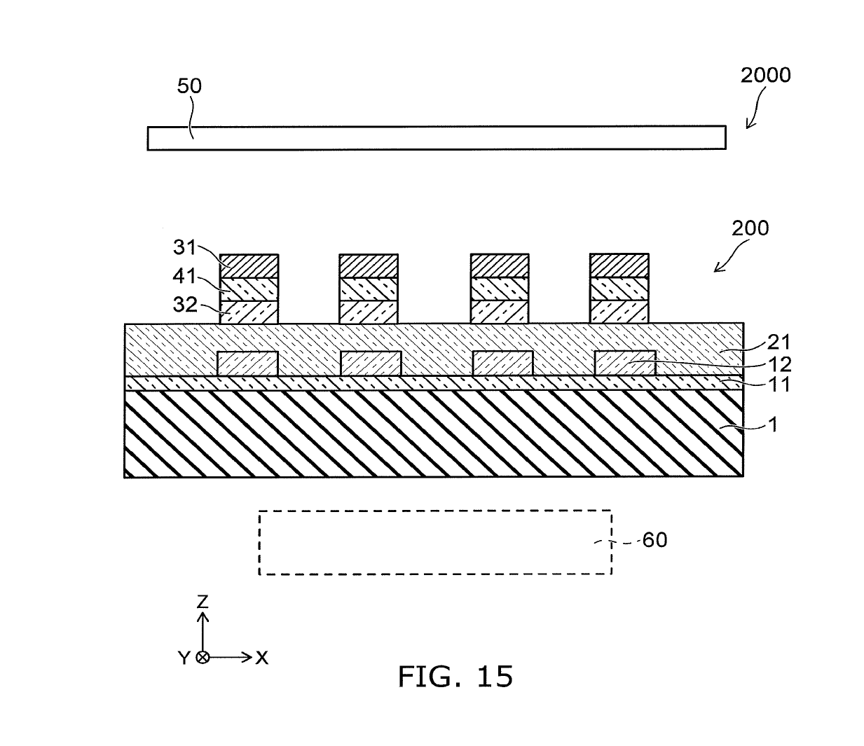

FIG. 15 is a schematic cross-sectional view illustrating an example of a detection device using the light-emitting element according to the second embodiment. As illustrated in FIG. 15, the detection device 2000 includes the light-emitting element 200, and the light detector 50 that detects the light radiated from the light-emitting layer 41.

In the detection device 2000, for example, the first layer 11, the multiple second layers 12, the light-transmitting layer 21, the multiple second electrodes 32, the multiple light-emitting layers 41, and the multiple first electrodes 31 are provided between at least a portion of the substrate 1 and at least a portion of the light detector 50.

For example, the detection object 60 is disposed so that at least a portion of the light-emitting element 200 is positioned between the light detector 50 and the detection object 60 as illustrated in FIG. 15. When the light is radiated from the light-emitting element 200, a portion of the light is incident on the detection object 60. For example, the biological signal of the detection object 60 is detected by the light being reflected by the detection object 60 and being incident on the light detector 50.

In the case where the second layer 12 is provided on the entire surface of the first layer 11, the light that is reflected or scattered by the detection object 60 toward the light detector 50 is undesirably scattered by the second layer 12. Conversely, by providing the second layer 12 to be divided, a portion of the light traveling toward the light detector 50 is incident on the light detector 50 by passing through the region where the second layer 12 is not provided. Therefore, it is possible to increase the light amount incident on the light detector 50.

According to the embodiment, similarly to the first embodiment, a light-emitting element and a detection device that are suited to the detection of a faint signal such as a pulse wave, etc., are provided.

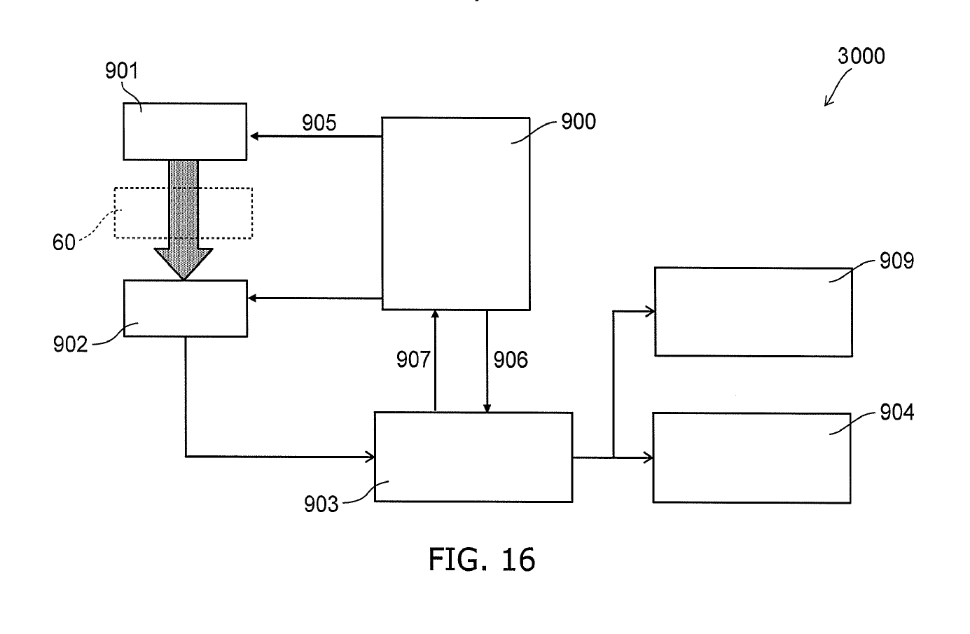

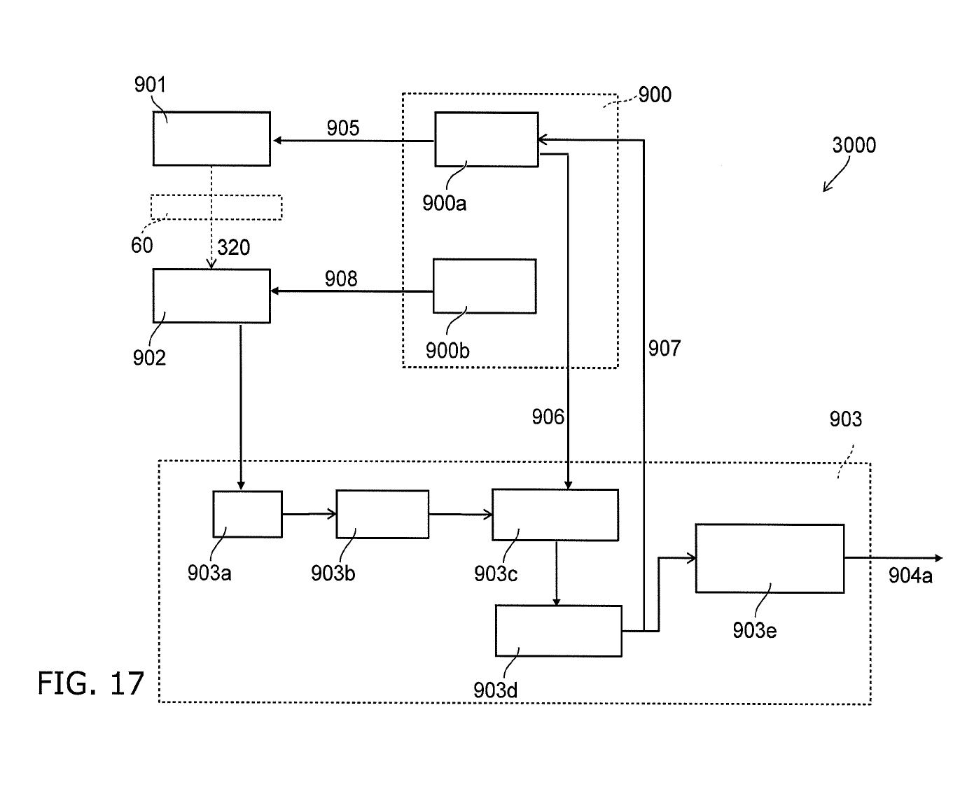

FIG. 16 and FIG. 17 are schematic views illustrating an example of a processing apparatus including the light-emitting element according to the embodiment. As illustrated in FIG. 16, the processing apparatus 3000 includes, for example, a controller 900, a light emitter 901, a light receiver 902, a signal processor 903, a recording device 904, and a display device 909.

The light emitter 901 includes the light-emitting element 100 according to the first embodiment or the light-emitting element 200 according to the second embodiment. The light receiver 902 includes a light detector detecting the light emitted from the light emitter 901. The light emitter 901 that receives an input signal from the controller 900 emits light. The light that is emitted passes through the detection object 60 or is reflected or scattered by the detection object 60, and is detected by the light receiver 902. The light receiver 902 may receive a bias signal from the controller 900 to increase the detection sensitivity.

The signal that is detected by the light receiver 902 is output to the signal processor 903. The signal processor 903 receives the signal from the light receiver 902 and performs processing of the signal such as, for example, AC detection, signal amplification, noise removal, etc., as appropriate. To perform the appropriate signal processing, the signal processor 903 may receive a synchronization signal from the controller 900. A feedback signal for adjusting the light amount of the light emitter 901 may be transmitted to the controller 900 from the signal processor 903. The signal that is generated by the signal processor 903 is stored in the recording device 904; and the information is displayed by the display device 909.

The processing apparatus 3000 may not include the recording device 904 and the display device 909. In such a case, the signal that is generated by the signal processor 903 is output to, for example, a recording device and a display device outside the processing apparatus 3000.

The processing apparatus 3000 will now be described more specifically with reference to FIG. 17. As illustrated in FIG. 17, the light emitter 901 receives an input signal 905 including a DC bias signal or a pulse signal from a pulse generator 900a of the controller 900. Light 320 that is emitted from the light emitter 901 passes through the detection object 60 or is reflected or scattered by the detection object 60, and is detected by the light receiver 902. The light receiver 902 may receive a bias signal from a bias circuit 900b of the controller 900. The signal that is detected by the light receiver 902 is input to the signal processor 903. After AC detection of the signal from the light receiver 902 is performed as necessary by the signal processor 903, the signal is amplified by an amplifier 903a; and unnecessary noise components are removed by a filter portion 903b. A signal synchronizer 903c receives the signal output from the filter portion 903b, and if appropriate, receives a synchronization signal 906 from the controller 900 and performs synchronization with the light 320.

The signal that is output from the signal synchronizer 903c is input to a signal shaper 903d. The processing apparatus 3000 may not include the signal synchronizer 903c. In such a case, the signal that is output from the filter portion 903b is input to the signal shaper 903d without going through the signal synchronizer 903c.

In the signal shaper 903d, the signal is shaped into the desired signal so that the appropriate signal processing is performed by a signal calculator 903e. For example, the signal shaping is performed by time averaging, etc. In the signal processor 903, the order of the AC detection and the processing performed by the processors is modifiable as appropriate. A calculated value 904a from the signal calculator 903e of the signal processor 903 is output to a recording device and a display device.

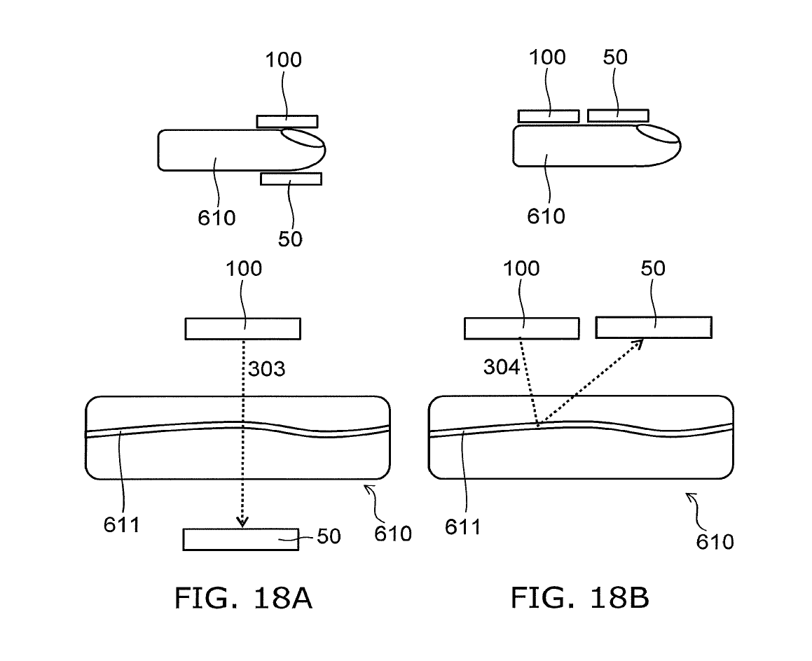

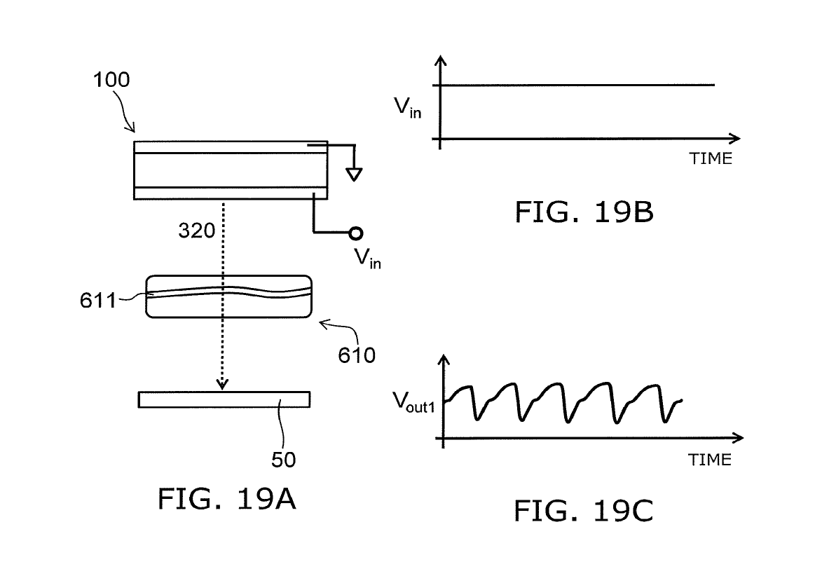

FIG. 18A to FIG. 21B are schematic views illustrating a pulse wave being measured using the light-emitting element 100 according to the first embodiment. The light-emitting element 200 according to the second embodiment may be used instead of the light-emitting element 100. FIGS. 18A and 18B illustrate the detection of the pulse wave of a blood vessel 611 inside a finger 610. Other than the finger 610, the living body location may be selected arbitrarily to be an ear, a chest, an arm, etc. In the example illustrated in FIG. 18A, light 303 that is emitted from the light-emitting element 100 passes through the blood vessel 611 and is detected by the light detector 50. In the example illustrated in FIG. 18B, light 304 that is emitted from the light-emitting element 100 is reflected or scattered by the blood vessel 611 and is detected by the light detector 50. At this time, the light detector 50 detects a signal reflecting the blood flow of the blood vessel 611. For example, the pulse is measured by the signal processor 903 shown in FIGS. 16 and 17 performing signal processing of the signal that is detected.

As illustrated in FIG. 19B, for example, a constant voltage is applied as an input signal Vᵢₙ to the first electrode 31 and the second electrode 32 of the light-emitting element 100. As illustrated in FIG. 19A, the light detector 50 detects the light passing through the finger 610 or the light reflected or scattered by the finger 610. At this time, as illustrated in FIG. 19C, the signal inside the blood is superimposed onto a signal Vₒᵤₜ detected by the light detector 50.

Or, as illustrated in FIG. 20A and FIG. 20B, the light may be radiated from the light-emitting element 100 by applying a pulse voltage as the input signal Vᵢₙ to the first electrode 31 and the second electrode 32 of the light-emitting element 100. As illustrated in FIG. 20C, the light on which the signal inside the blood is superimposed is detected by the light detector 50.

FIG. 21A and FIG. 21B illustrate an example of the optical signal detected in the case where a pulse voltage is applied as the input signal Vᵢₙ. FIG. 21B illustrates the enlarged portion surrounded with the broken line of FIG. 21A. In the case where the frequency of the pulse wave is sufficiently faster than the frequency of the pulse voltage applied to the light-emitting element 100, the pulse wave signal is obtained by viewing only the optical signal of each light pulse as illustrated in FIG. 21A and FIG. 21B. Typically, the pulse wave is about 1 Hz; and the frequency of the pulse voltage may be set to, for example, 100 Hz to 100 KHz. Because the time that the light-emitting element 100 emits light is shorter for the configuration in which the pulse voltage illustrated in FIG. 20A to FIG. 21B is used than for the configuration in which the constant voltage illustrated in FIGS. 19A to 19C is used, this is advantageous in that the degradation of the light-emitting element 100 is suppressed; and the power consumption can be reduced.

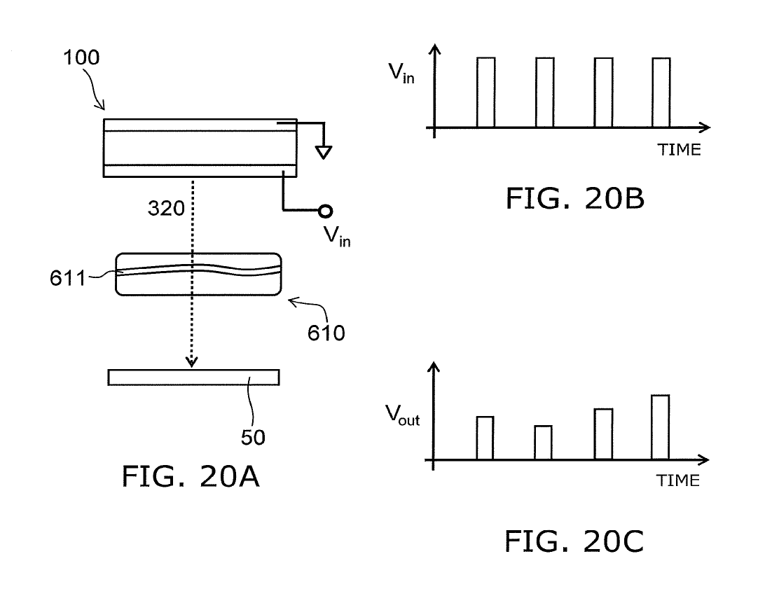

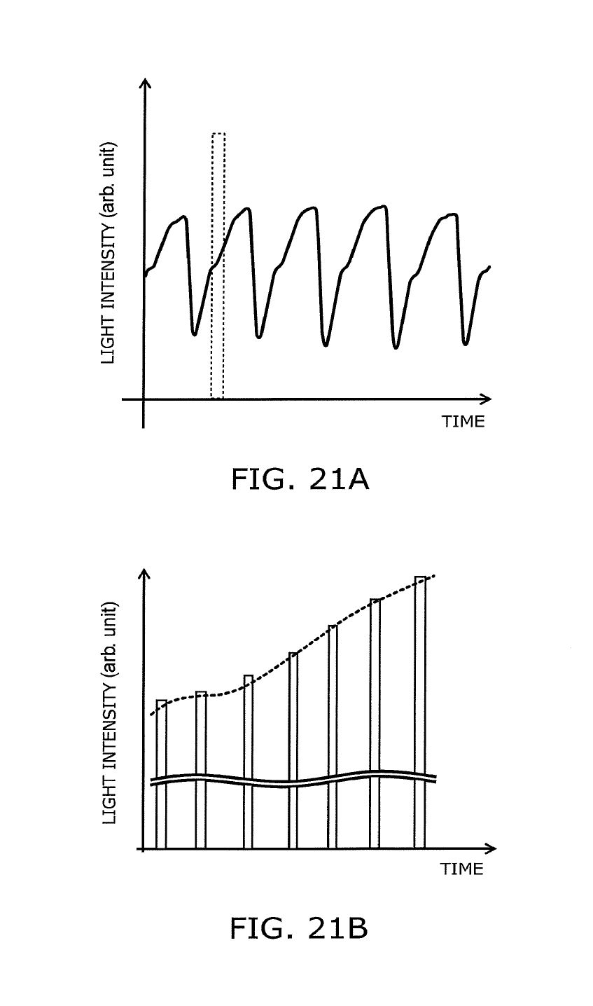

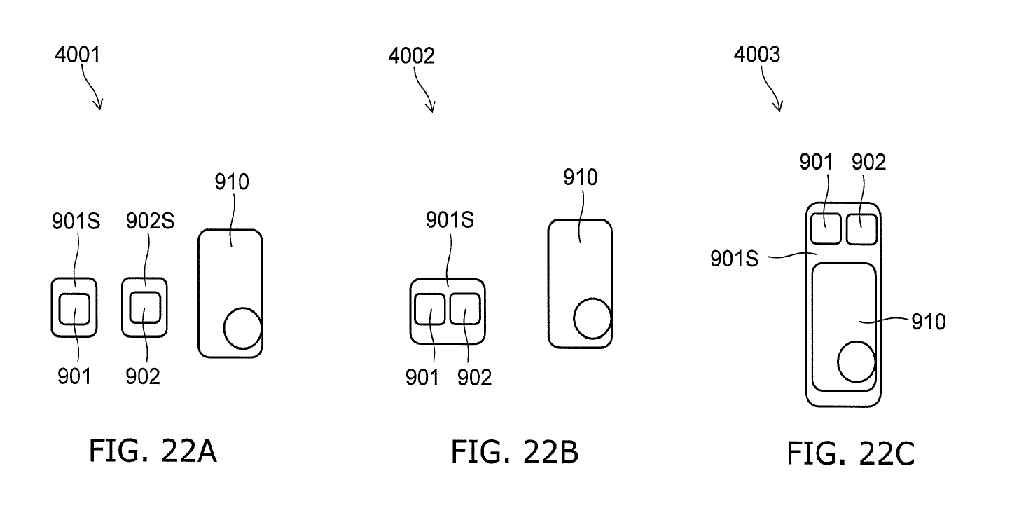

FIG. 22A to FIG. 22C are schematic views illustrating processing apparatuses including the light-emitting element according to the embodiment. The processing apparatuses 4001 to 4003 include the light emitter 901, the light receiver 902, and a controller/signal processor 910. The light emitter 901 includes the light-emitting element according to the embodiment.

In the processing apparatus 4001, the light emitter 901 is provided on a support substrate 901S; and the light receiver 902 is provided on a support substrate 902S. The processing apparatus 4001 has a configuration in which the light emitter 901, the light receiver 902, and the controller/signal processor 910 are provided independently from each other.

In the processing apparatus 4002, the light emitter 901 and the light receiver 902 are provided on a common support substrate 901S. In the processing apparatus 4003, the light emitter 901, the light receiver 902, and the controller/signal processor 910 are provided on a common support substrate 901S. The controller/signal processor 910 and one of the light emitter 901 or the light receiver 902 may be provided on a common support substrate.

Thus, various configurations are employable as the configuration of the processing apparatus.

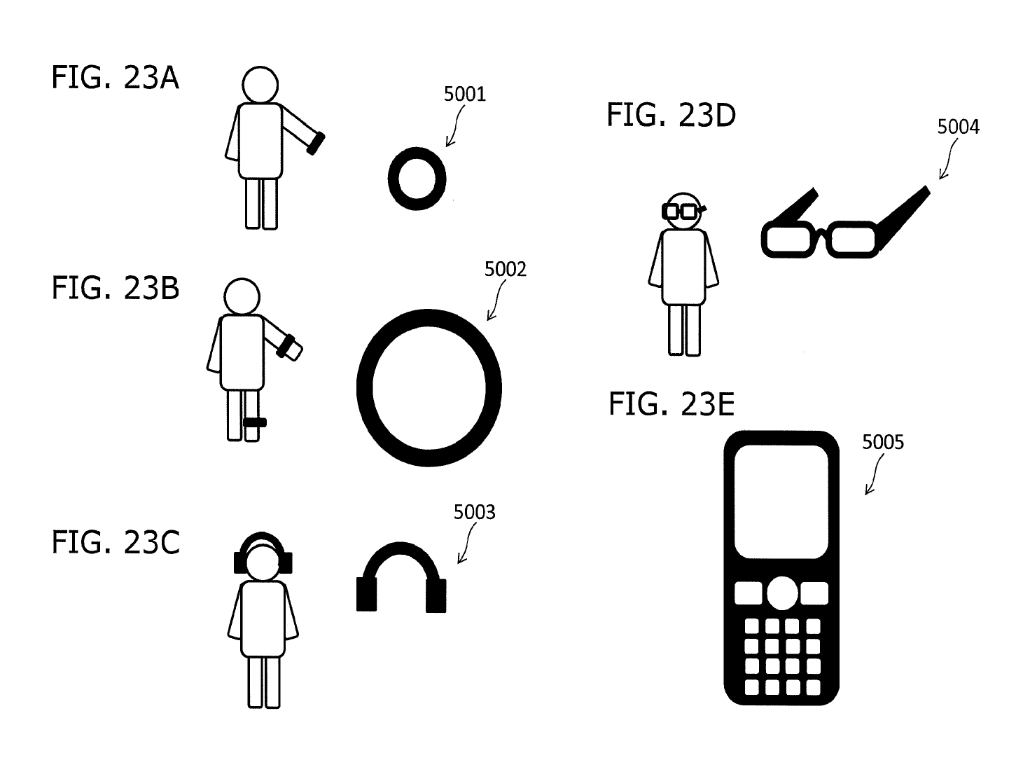

FIG. 23A to FIG. 23E are schematic views illustrating applications of processing apparatuses including the light-emitting element according to the embodiment. The processing apparatus in each example measures, for example, the pulse and/or the oxygen concentration of blood.

In the example illustrated in FIG. 23A, a processing apparatus 5001 is included in a finger ring. For example, the processing apparatus 5001 detects the pulse of a finger contacting the processing apparatus 5001. In the example illustrated in FIG. 23B, a processing apparatus 5002 is included in an arm band. For example, the processing apparatus 5002 detects the pulse of an arm or a leg contacting the processing apparatus 5002.

In the example illustrated in FIG. 23C, a processing apparatus 5003 is included in an earphone. In the example illustrated in FIG. 23D, a processing apparatus 5004 is included in eyeglasses. For example, the processing apparatuses 5003 and 5004 detect the pulse of an ear lobe. In the example illustrated in FIG. 23E, a processing apparatus 5005 is included in a button, a screen, etc., of a mobile telephone or a smartphone. For example, the processing apparatus 5005 detects the pulse of a finger touching the processing apparatus 5005.

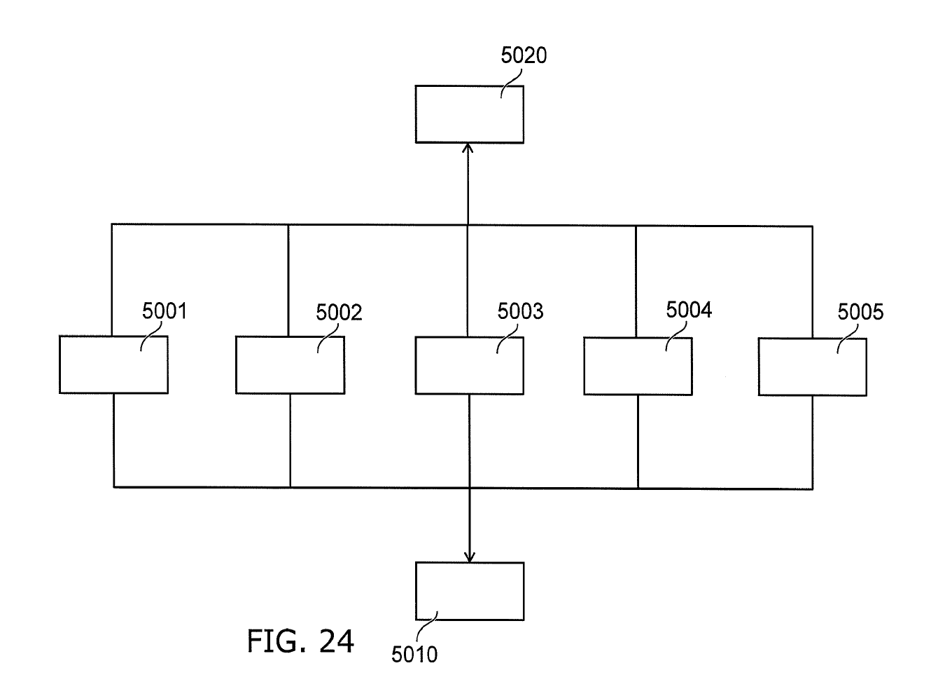

FIG. 24 is a schematic view illustrating a system using the processing apparatuses illustrated in FIGS. 23A to 23E.

For example, the processing apparatuses 5001 to 5005 transmit the measured data to a device 5010 such as a desktop PC, a notebook PC, a tablet terminal, etc., by a wired or wireless method. Or, the processing apparatuses 5001 to 5005 may transmit the data to a network 5020.

The data that is measured by the processing apparatuses can be monitored by utilizing the device 5010 or the network 5020. Or, monitoring or statistical processing may be performed by analyzing the measured data by using an analysis program, etc. In the case where the measured data is a pulse or an oxygen concentration of blood, the summary of the data may be performed at any time interval. For example, the data that is summarized is utilized for health care. At a hospital, for example, the data is utilized for continuous monitoring of the health condition of a patient.

According to the embodiments recited above, a light-emitting element, a detection device, and a processing apparatus that are suited to the detection of a faint signal such as a pulse wave, etc., can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the invention is not limited to these specific examples. For example, one skilled in the art may similarly practice the invention by appropriately selecting specific configurations of components included in the light-emitting element, the detection device, and the processing apparatus such as the substrate 1, the light-transmitting layer 21, the first electrode 31, the second electrode 32, the light-emitting layer 41, the third layer 43, the fourth layer 44, the support portion 121, the particle 122, the controller 900, the light receiver 902, the signal processor 903, the recording device 904, and the display device 909, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all light-emitting elements, all detection devices, and all processing apparatuses practicable by an appropriate design modification by one skilled in the art based on the light-emitting elements, the detection devices, and the processing apparatuses described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light-emitting element, comprising:
a substrate, the substrate being light-transmissive;
a first electrode;
a first layer having a refractive index lower than a refractive index of the substrate and being light-transmissive, at least a portion of the first layer being provided between the first electrode and a portion of the substrate;
a second electrode provided between the first electrode and at least a portion of the first layer, the second electrode being light-transmissive;
a light-emitting layer provided between the first electrode and the second electrode; and
a second layer, the second layer being light-transmissive and configured to modify a travel direction of light incident on the second layer, at least a portion of the second layer being provided between the first electrode and at least a portion of the first layer.

2. The element according to claim 1, wherein the second layer scatters the light incident on the second layer.

3. The element according to claim 1, wherein
the second layer includes a plurality of particles, and
a diameter of at least one of the plurality of particles is greater than 1/10 of a peak wavelength of light radiated from the light-emitting layer.

4. The element according to claim 3, wherein
the second layer further includes a support portion including at least one of a polymer or a resin,
the support portion is provided around at least one of the plurality of particles, and
the absolute value of a difference between a refractive index of at least one of the plurality of particles and a refractive index of the support portion is 0.1 or more.

5. The element according to claim 1, wherein
the second layer includes a first portion and a second portion,
the first portion is provided around the second portion at a plane crossing a first direction, the first direction being from the second electrode toward the first electrode, and
a refractive index of the second portion is lower than a refractive index of the first portion.

6. The element according to claim 5, wherein
a plurality of the second portions is provided, and
the plurality of second portions is provided to be separated from each other.

7. The element according to claim 1, wherein the light-emitting layer includes an organic substance.

8. The element according to claim 1, wherein
the second layer is provided in at least one of a first position or a second position,
the first position is between the first layer and the second electrode, and
the second position is between the first electrode and the light-emitting layer.

9. The element according to claim 1, wherein
a thickness along a first direction of the first layer is 10 nm or more, the first direction being from the second electrode toward the first electrode, and
the thickness of the first layer is not more than a thickness along the first direction of the substrate.

10. The element according to claim 1, wherein
the light-emitting layer includes a light-emitting region overlapping the first electrode and the second electrode in a first direction, the first direction being from the second electrode toward the first electrode, and
a length X (mm) of the light-emitting region along a second direction and a thickness T (mm) of the substrate along the first direction satisfy
X<53.16×T−0.23,
the second direction being perpendicular to the first direction.

11. The element according to claim 10, wherein the length X (mm), the thickness T (mm), and a refractive index n of the substrate satisfy
X<2×T×tan(arcsin g(1/n))

12. The element according to claim 1, wherein
a plurality of the first electrodes is provided,
a plurality of the light-emitting layers is provided,
a plurality of the second electrodes is provided,
the plurality of second electrodes is provided respectively between a portion of the substrate and the plurality of first electrodes, and
the plurality of light-emitting layers is provided respectively between the plurality of first electrodes and the plurality of second electrodes.

13. The element according to claim 12, wherein
a plurality of the second layers is provided, and
the plurality of second layers is provided respectively between a portion of the first layer and the plurality of second electrodes.

14. The element according to claim 1, wherein the refractive index of the first layer is 1.4 or less.

15. The element according to claim 1, wherein the first layer includes at least one of a polymer or an aerogel.

16. The element according to claim 1, wherein a refractive index of the second layer is the same as or higher than the refractive index of the substrate.

17. A detection device, comprising:
the light-emitting element according to claim 1; and
a sensor detecting light radiated from the light-emitting element.

18. The device according to claim 17, wherein at least a portion of the sensor overlaps at least a portion of the light-emitting element in a first direction, the first direction being from the second layer toward the first layer.

19. The device according to claim 17, wherein at least a portion of the sensor overlaps at least a portion of the light-emitting element in a second direction perpendicular to a first direction, the first direction being from the second layer toward the first layer.

20. A processing apparatus, comprising:
the detection device according to claim 17; and
a processor receiving and processing a signal detected by the detection device.
